(19) United States
(12) Patent Application Publication
(10) Pub. No.: US 2017/0047377 A1
(43) Pub. Date: Feb. 16, 2017

(54) MEMORY DEVICE AND METHOD FOR MANUFACTURING THE SAME

(71) Applicant: MACRONIX INTERNATIONAL CO., LTD., Hsinchu (TW)

(72) Inventors: Erh-Kun Lai, Taichung City (TW); Kuang-Hao Chiang, Taoyuan City (TW)

(21) Appl. No.: 14/826,264

(22) Filed: Aug. 14, 2015

(51) Int. Cl. H01L 27/24; H01L 45/00

(52) U.S. Cl. CPC H01L 27/2418; H01L 45/1233; H01L 45/1608; H01L 45/1683; H01L 45/1675

(57) ABSTRACT

A memory device is provided. The memory device includes a substrate, a plurality of alternately stacked semiconductor layers and oxide layers disposed on the substrate, at least one through hole penetrating the stacked semiconductor layers and oxide layers, and an electrode layer disposed in the through hole. Each of the semiconductor layers includes a first area having a first conductive type and a second area having a second conductive type opposite to the first conductive type.

### TECHNICAL FIELD

The disclosure relates in general to a memory device and a method for manufacturing the same, and more particularly to a resistive random-access memory (RRAM) device with PN or PIN diodes and a method for manufacturing the same.

### BACKGROUND

Memory devices are used in storage elements for many products, such as MP3 players, digital cameras, computer files, etc. As the application increases, the demand for the memory device focuses on small size and large memory capacity.

As a candidate for nonvolatile memory applications of next generation, resistive random-access memory attracts abundant attention due to its simple metal-insulator-metal structure, excellent scalability, fast switching speed, low-voltage operation and good compatibility with CMOS technology.

Designers develop a method for improving the memory device density, using 3D stack memory device so as to increase the memory capacity and decrease the cost per cell. However, multiple leakage paths may exist in cross-point arrays in the 3D stack memory device, and the multiple leakage paths may limit the array size of the memory device and increase the power consumption. Therefore, it is important to manufacture a memory which can effectively reduce the multiple leakage paths.

### SUMMARY

The disclosure is directed to a resistive random-access memory device with PN or PIN diodes and a method for manufacturing the same. By the inserted PN or PIN structure, the leakage current may be effectively reduced.

According to one embodiment, a memory device is provided. The memory device includes a substrate, a plurality of alternately stacked semiconductor layers and oxide layers disposed on the substrate, at least one through hole penetrating the stacked semiconductor layers and oxide layers, and an electrode layer disposed in the through hole. Each of the semiconductor layers includes a first area having a first conductive type and a second area having a second conductive type opposite to the first conductive type.

According to another embodiment, a method for manufacturing a memory device is provided. The method includes the following steps. A substrate is provided. A plurality of semiconductor layers and oxide layers are alternately stacked on the substrate, and the semiconductor layers have a first conductive type. The stacked semiconductor layers and oxide layers are etched along a direction perpendicular to surfaces of the stacked semiconductor layers and oxide layers to form at least one through hole. A portion of the semiconductor layers is etched along a direction parallel with the surfaces the stacked semiconductor layers and oxide layers to form a plurality of spaces. Semiconductor material having a second conductive type opposite to the first conductive type is deposited in the spaces, such that each of the semiconductor layers is divided into a first area and a second area. An electrode layer is deposited in the through hole.

### BRIEF DESCRIPTION OF THE DRAWINGS

FIG. 1A illustrates a top view of the memory device in one embodiment according to the disclosure.

FIG. 1B illustrates a cross-section view of the memory device along A-A′ line in FIG. 1A.

FIG. 2A to 5B illustrate a process for manufacturing the memory device in one embodiment according to the disclosure.

FIG. 6 illustrates a top-view of another array layout of the memory device in one embodiment according to the disclosure.

FIG. 7 illustrates a schematic diagram of decoding the memory device in one embodiment according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The embodiments are described in details with reference to the accompanying drawings. The identical elements of the embodiments are designated with the same reference numerals. Also, it is important to point out that the illustrations may not be necessarily drawn to scale, and there may be other embodiments of the present disclosure which are not specifically illustrated. Thus, the specification and the drawings are regarded as an illustrative sense rather than a restrictive sense.

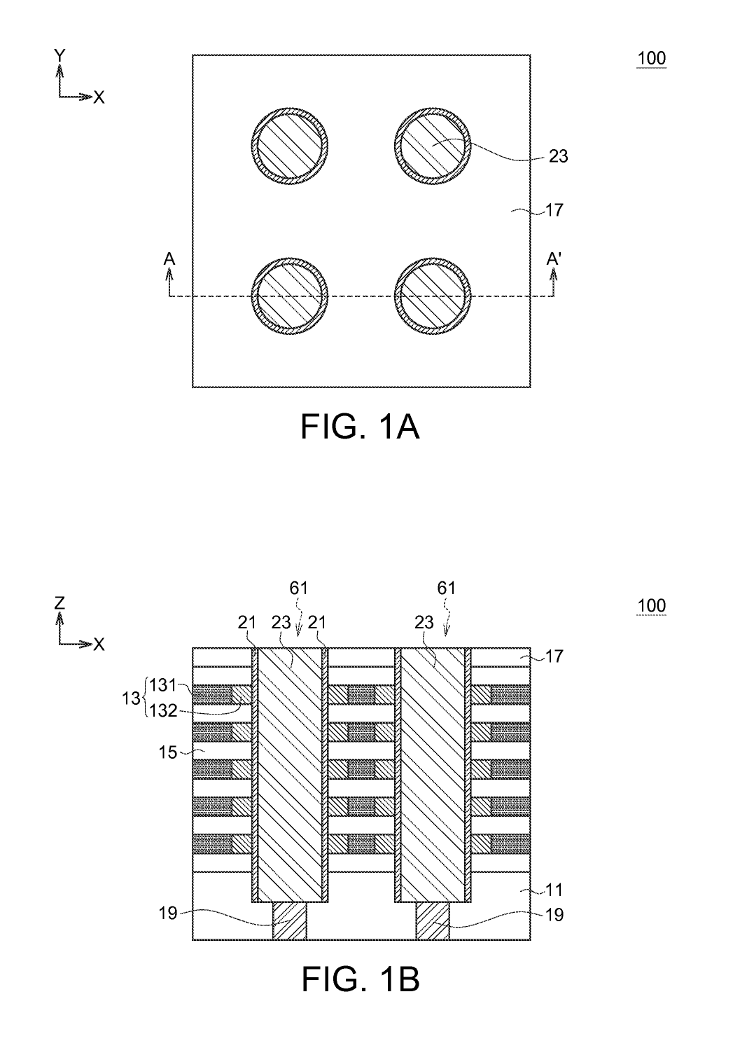

FIG. 1A illustrates a top view of the memory device 100 in one embodiment according to the disclosure. FIG. 1B illustrates a cross-section view of the memory device 100 along A-A′ line in FIG. 1A. In the embodiment according to the disclosure, the memory device 100 may include a substrate 11, a plurality of alternately stacked semiconductor layers 13 and oxide layers 15 disposed on the substrate 11, at least one through hole 61 penetrating the stacked semiconductor layers 13 and oxide layers 15, and an electrode layer 23 disposed in the through hole 61.

As shown in FIG. 1B, each of the semiconductor layers 13 may include a first area 131 having a first conductive type and a second area 132 having a second conductive type, and the second conductive type is opposite to the first conductive type.

In this embodiment, the memory device 100 may also include an isolation layer 21 formed along the periphery of the through hole 61. Besides, the second area 132 of each of the semiconductor layers 13 is adjacent to the isolation layer 21, and the first area 131 each of of the semiconductor layers 13 is adjacent to the second area 132.

Further, the concentration of the second area 132 closer to the isolation layer 21 is larger than the concentration of the second area 132 farther away from the isolation layer 21 (closer to the first area 131). In this embodiment, the semiconductor layers 13 may be used as PN or PIN diodes. For example, the first conductive type of the first area 131 may be N-type, and the second conductive type of the second area 132 may be P-type.

As shown in FIG. 1B, the memory device 100 may also include a conductive plug 19 disposed in the substrate 11. In this embodiment, the conductive plug 19 may be electrically connected to the electrode layer 23. Further, the memory device 100 may also include a hard mask 17 formed on the alternately stacked semiconductor layers 13 and oxide layers 15 as shown in FIG. 1A and FIG. 1B.

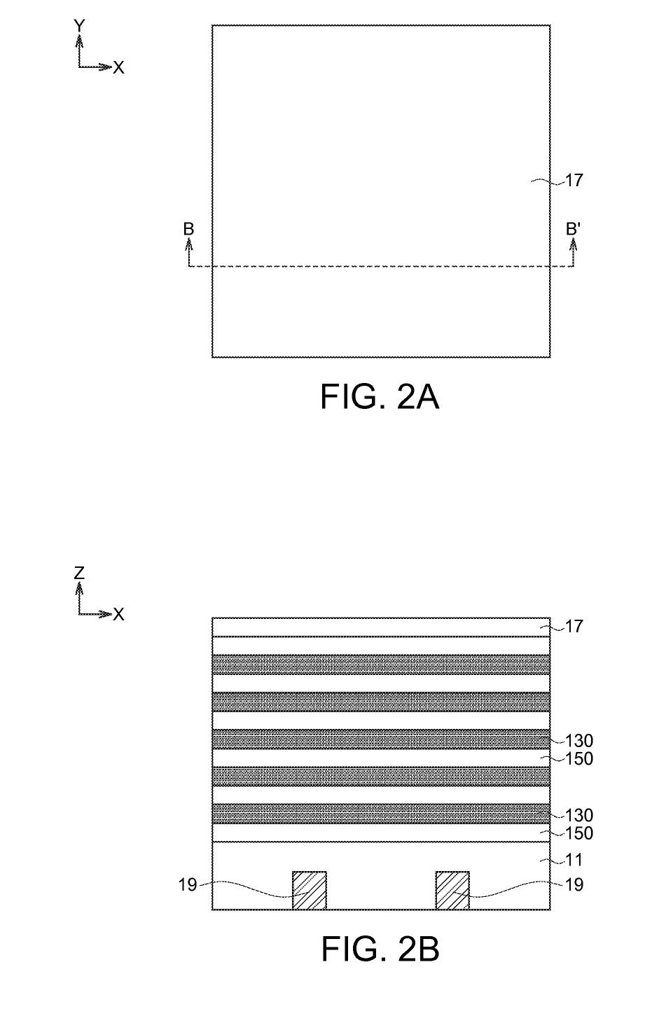

FIG. 2A to 5B illustrate a process for manufacturing the memory device 100 in one embodiment according to the disclosure. First, a substrate 11 is provided. Then, a plurality of semiconductor layers 130 and oxide layers 150 are alternately stacked on the substrate 11. In this embodiment, the semiconductor layers 130 may have a first conductive type, such as N-type. Besides, a hard mask 17 may be formed on the alternately stacked semiconductor layers 130 and oxide layers 150. In one embodiment, the hard mask 17 may include silicon nitride (SiN).

FIG. 2A illustrate a top-view of the memory device in this stage. FIG. 2B illustrates a cross-section view of the memory device along B-B′ line in FIG. 2A. As shown in FIG. 2B, a conductive plug 19 may be formed in the substrate 11. In one embodiment, the conductive plug 19 may include tungsten (W), and be connected to a vertical or planar complementary metal-oxide-semiconductor (CMOS) decoder (not shown).

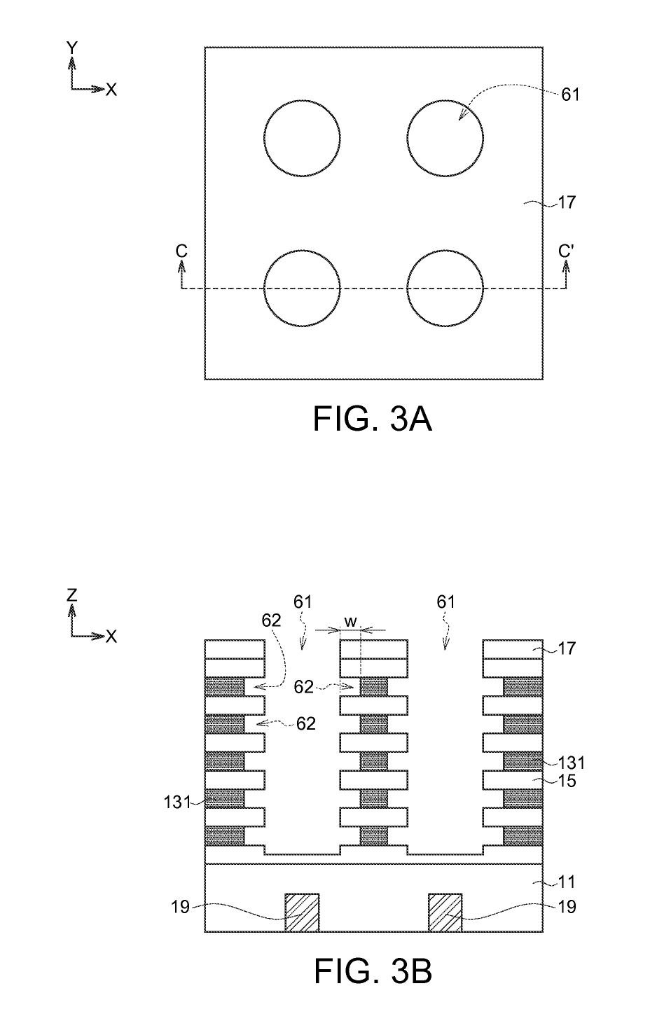

FIG. 3A illustrate a top-view of the memory device in next stage. FIG. 3B illustrates a cross-section view of the memory device along C-C′ line in FIG. 3A. As shown in FIG. 3A and FIG. 3B, the stacked semiconductor layers 130 and oxide layers 150 may be etched along a direction (Z-direction) perpendicular to surfaces of the stacked semiconductor layers 130 and oxide layers 150 to form at least one through hole 61.

Besides, a portion of the semiconductor layers 130 may be etched along a direction (X-direction) parallel with the surfaces the stacked semiconductor layers 130 and oxide layers 150 to form a plurality of spaces 62. As shown in FIG. 3B, after the etching process, the first area 131 of the semiconductor layer and the oxide layer 15 may be remained.

In this embodiment, a chemical dry etching (CDE) may be implemented to etch the portion of the semiconductor layers 130 along the direction (X-direction) parallel with the surfaces the stacked semiconductor layers 130 and oxide layers 150. That is, an isotropic etching may be implemented to form the spaces 62 along X-direction.

Besides, the width W of the spaces 62 along X-direction may be between 20 and 200 nm.

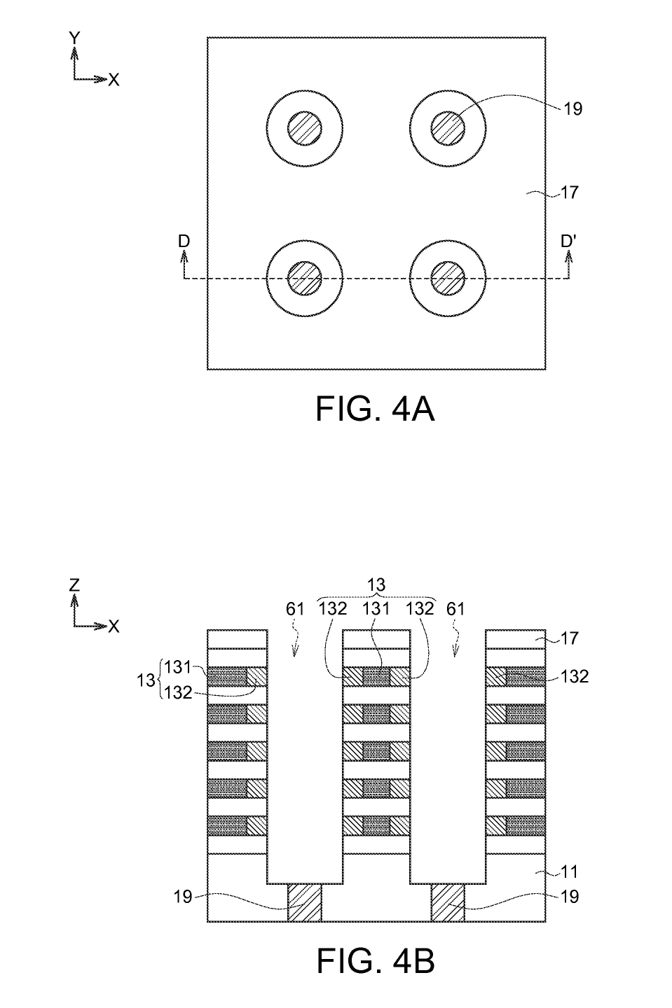

FIG. 4A illustrate a top-view of the memory device in next stage. FIG. 4B illustrates a cross-section view of the memory device along D-D′ line in FIG. 4A. As shown in FIG. 4B, semiconductor material having a second conductive type may be deposited in the spaces 62, such that each of the semiconductor layers 13 may be divided into the first area 131 and the second area 132.

In this embodiment, the conductive type of the second area 132 may be P-type. Besides, the deposition of the second area 132 may be selective polysilicon deposition or selective epitaxial growth (SEG) silicon deposition. Further, the semiconductor layers 13 may be used as PN or PIN diodes. Here, if the first area 131 is N type, then the second area 132 is P type; if the first area 131 is P type, then the second area 132 is N type.

Furthermore, the concentration of the second area 132 of the semiconductor layer 13 may not be uniform. For example, selective undoped polysilicon may be deposited first. Then, selective P−−/P−/P/P+ polysilicon may be deposited gradually. In some embodiment, an etching back process may be implemented to pull the second area 132 of each of the semiconductor layer 13 back inside the spaces 62, and the deposited semiconductor material would not remain on the surfaces of the oxide layers 15.

Since the width W of the spaces 62 along X-direction may be between 20 and 200 nm, the width of the second area 132 along X-direction may also be between 20 and 200 nm.

Then, the substrate 11 may be etched along Z-direction to expose the conductive plug 19. Here, the etching process may stop on the surface of the conductive plug 19 or a portion of the conductive plug 19 may also be etched. The disclosure is not limited in the illustrated structure in FIG. 4B.

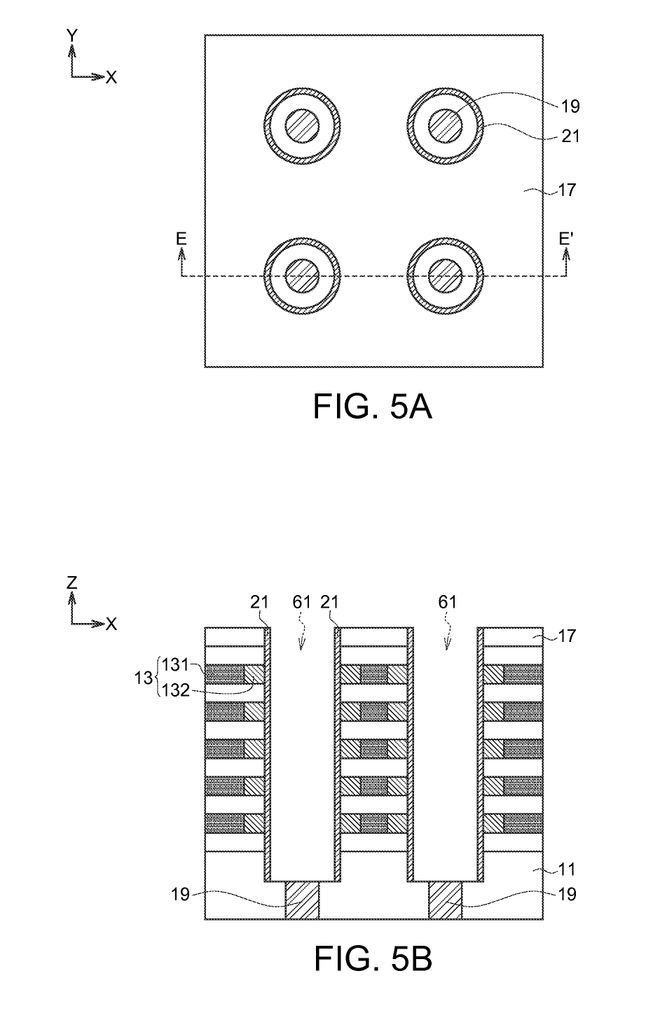

FIG. 5A illustrate a top-view of the memory device in next stage. FIG. 5B illustrates a cross-section view of the memory device along E-E′ line in FIG. 5A. As shown in FIG. 5A and FIG. 5B, an isolation layer 21 is formed along the periphery of the through hole 61. Here, the isolation layer 21 may include metal oxide or phase change material (PCM).

In one embodiment, the second area 132 of each of the semiconductors 13 may be adjacent to the isolation layer 21, and the first area 131 of each of the semiconductors 13 may be adjacent to the second area 132. That is, the concentration of the second area 132 closer to the isolation layer 21 may be larger than the concentration of the second area 132 farther away from the isolation layer 21.

Then, an electrode layer 23 is deposited in the through hole 61 to form the memory device 100 as shown in FIG. 1A and FIG. 1B. Here, the electrode layer 23 may fill the through hole 61 and be electrically connected to the conductive plug 19.

In some embodiment, chemical mechanical polishing/planarization (CMP) process may be implemented and stopped on the hard mask 17 after depositing the electrode layer 23.

In the embodiment mentioned above, the through hole 61 is round, such that a gate-all-around (GAA) structure may be formed. The gate-all-around structure may be a hole type array layout. However, the disclosure is not limited thereto.

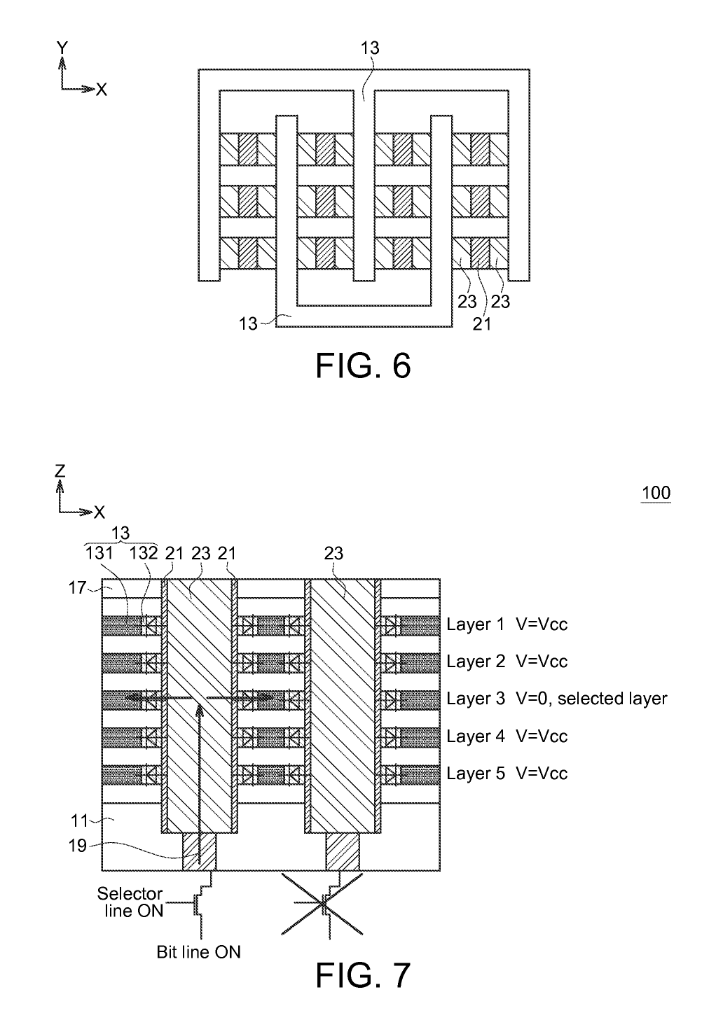

FIG. 6 illustrates a top-view of another array layout of the memory device in one embodiment according to the disclosure. As shown in FIG. 6, the array layout of the memory device may be a line type (or interdigital type) array layout. The structure shown in FIG. 6 may also have a cross-section view as shown in FIG. 1B. The line type array layout could be physical 2 bits/per cell, and even and odd lines may be decoded individually.

FIG. 7 illustrates a schematic diagram of decoding the memory device 100 in one embodiment according to the disclosure. Here, vertical and planar CMOS may be operated to decode the selected conductive plug 19 (1st and 2nd decoding). Then, layer selector (semiconductor layer 13) may be operated to decode the selected layer.

For example, the left conductive plug 19 and Layer 3 are selected as shown in FIG. 7, so that the selector line and the bit line on the left side are ON, and the voltage V in Layer 3 (selected layer) may be zero, while other layers (Layers 1, 2, 4, and 5) may be applied Vcc. If the first area 131 is P type, then the second area 132 is N type. Further, if the first area 131 is P type, then the voltage of Layer 1,2,4,5 is 0, and the voltage of the selected Layer 3 is Vcc.

According to the embodiments of the disclosure mentioned above, the semiconductor layers 13 of the memory device 100 may be used as selectors (PN or PIN diodes) to reduce the leakage current, and effectively solve the problems caused by the leakage current. Further, the manufacturing method of the memory device 100 is similar to the manufacturing method of 3D NAND flash memory.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A memory device, comprising:
a substrate;
a plurality of alternately stacked semiconductor layers and oxide layers disposed on the substrate;
a through hole penetrating the stacked semiconductor layers and oxide layers; and
an electrode layer disposed in the through hole,
wherein each of the semiconductor layers comprises a first area having a first conductive type and a second area having a second conductive type opposite to the first conductive type;
an array layout of the memory device is a line type array layout;
the line type array layout is physical 2 bits/per cell; and
even and odd lines of the array layout are decoded individually.

2. The memory device according to claim 1, further comprising:
an isolation layer formed along a periphery of the through hole.

3. The memory device according to claim 2, wherein the second area is adjacent to the isolation layer, and the first area is adjacent to the second area.

4. The memory device according to claim 3, wherein a concentration of the second area closer to the isolation layer is larger than a concentration of the second area farther away from the isolation layer.

5. The memory device according to claim 2, wherein the isolation layer comprises metal oxide or phase change material.

6. The memory device according to claim 1, further comprising:
a conductive plug disposed in the substrate,
wherein the conductive plug is electrically connected to the electrode layer.

7. The memory device according to claim 1, further comprising:
a hard mask disposed on the alternately stacked semiconductor layers and oxide layers.

8. The memory device according to claim 7, wherein the hard mask comprises silicon nitride.

9. (canceled)

10. The memory device according to claim 1, wherein a width of the second area is between 20 and 200 nm.

11. The memory device according to claim 1, wherein the first conductive type is N-type, and the second conductive type is P-type.

12. A method for manufacturing a memory device, comprising:
providing a substrate;
alternately stacking a plurality of semiconductor layers and oxide layers on the substrate, wherein the semiconductor layers have a first conductive type;
etching the stacked semiconductor layers and oxide layers along a direction perpendicular to surfaces of the stacked semiconductor layers and oxide layers to form at least one through hole;
etching a portion of the semiconductor layers along a direction parallel with the surfaces of the stacked semiconductor layers and oxide layers to form a plurality of spaces;
depositing semiconductor material having a second conductive type opposite to the first conductive type in the spaces, such that each of the semiconductor layers is divided into a first area and a second area; and
depositing an electrode layer in the through hole.

13. The method according to claim 12, further comprising:
forming an isolation layer along a periphery of the through hole.

14. The method according to claim 13, wherein the second area is adjacent to the isolation layer, and the first area is adjacent to the second area.

15. The method according to claim 14, wherein a concentration of the second area closer to the isolation layer is larger than a concentration of the second area farther away from the isolation layer.

16. The method according to claim 13, wherein isolation layer comprises metal oxide or phase change material.

17. The method according to claim 12, further comprising:
forming a conductive plug in the substrate,
wherein the conductive plug is electrically connected to the electrode layer.

18. The method according to claim 12, further comprising:
forming a hard mask on the alternately stacked semiconductor layers and oxide layers,
wherein the hard mask comprises silicon nitride.

19. The method according to claim 12, wherein a width of the second area is between 20 and 200 nm.

20. The method according to claim 12, wherein the first conductive type is N-type, and the second conductive type is P-type.
